(19) United States
(12) Patent Application Publication
(10) Pub. No.: US 2004/0065410 A1
(43) Pub. Date: Apr. 8, 2004

(54) Method and apparatus for dispensing interface materials

(75) Inventors: Vadim Gektin, San Jose, CA (US); Deviprasad Malladi, Fremont, CA (US)

Correspondence Address: ZAGORIN O'BRIEN & GRAHAM, L.L.P., 7600B N. CAPITAL OF TEXAS HWY., SUITE 350, AUSTIN, TX, 78731, US

(73) Assignee: Sun Microsystems, Inc.

(21) Appl. No.: 10/264,675

(22) Filed: Oct. 4, 2002

(51) Int. Cl. H05K 7/20

(52) U.S. Cl. 156/291; 361/709

(57) ABSTRACT

The present application describes an apparatus and method for dispensing interface materials for electronic packages. According to some embodiments, a cooling radiator is attached using adhesive interface material (e.g., on the perimeter, edges, distributed spots or the like) to an electronic package. After the adhesive interface material cures, the thermal interface material is dispensed (e.g., thorough an opening in the cooling radiator, adhesive interface material or the like). The dispensing of the thermal interface material does not leave a gap between the adhesive interface material and thermal interface material thus providing a better thermal performance and hence, enhanced power dissipation for the electronic package.

### BACKGROUND

1. Field of the Invention

The present invention relates to electronic packaging and more specifically to interface material dispensing in electronic packages.

2. Description of the Related Art

Generally, in electronic packaging, interface materials (e.g., thermal, adhesive or the like) are used to attach a cooling radiator (e.g., heat sink or the like) to an electronic package (e.g., integrated circuit or the like). Typically, the interface materials have low thermal conductivity which limits the amount of heat that can be dissipated by the electronic package. The limited capacity to dissipate heat severely restricts the maximum power that can be used and dissipated by the electronic package thus limiting the performance of the integrated circuit within the electronic package. One solution is to use adhesive interface materials with higher thermal performance to attach the cooling radiator to the electronic package. However, typically, the interface materials with higher thermal performance have lower adhesion strength causing the cooling radiators to fall off the electronic package.

FIG. 1A illustrates an example of a typical use of interface material to attach a cooling radiator to an electronic package. A circuit board 110 includes an electronic package 120. For purposes of illustration, in the present example, one electronic package is shown however, one skilled in art will appreciate that a circuit board can include a combination of various electronic components (discrete, integrated or the like) used with various cooling radiators. A cooling radiator 130 is attached to electronic package 120 via interface material 140. In the present example, a heat sink is used as the cooling radiator however one skilled in art will appreciate that any cooling radiator can be used for heat dissipation.

FIG. 1B is the top view of electronic package 120 with cooling radiator 130 removed illustrating a typical use of interface material. Typically, adhesive thermal interface material 140 covers the entire surface area on the top of electronic package 120 to provide a better adhesive and conductive interface for cooling radiator 140. With higher thermal performance, adhesive thermal interface material 140 typically has lower adhesion strength causing cooling radiator 130 to fall off electronic package 120.

Another solution is to use a combination of adhesive interface material and high performance thermal interface material. Typically, an interface material with higher thermal performance is used with another interface material with better adhesive property. The adhesive interface material is dispensed on the perimeters of the electronic package to attach the cooling radiator to the electronic package and thermal interface material is dispensed on the surface area within the perimeters to provide a better thermally conductive interface with the cooling radiator. To prevent the interaction (e.g., chemical or the like) between the two interface materials and maximize the functionality of each interface material, a gap (e.g., air gap or the like) is created between the two materials during the dispensing process. However, the gap between the interface materials reduces the thermal efficiency of the cooling radiator.

FIG. 2 is the top view of an electronic package 220 without a cooling radiator illustrating a typical use of a combination of two interface materials to attach the cooling radiator to electronic package 220. A circuit board 210 includes an electronic package 220. The top surface area of electronic package 220 includes two interface materials, interface materials 230 and 240. In the present example, interface material 230 has adhesive properties and is used on the perimeter or the edges of electronic package 220 and interface material 240 is high performance thermal interface material and is used on the middle portion of electronic package 220 to provide a better conductive interface with the cooling radiator.

Typically, it is ensured that the interface materials 230 and 240 do not mix with each other to prevent a change in the material properties of the combination of the interface materials during electronic package processing. Therefore, the dispense pattern of interface materials 230 and 240 is critical. Generally, each material is dispensed and cured separately on electronic package 220 and a gap 250 is left between the two interface materials. However, gap 250 results in the reduction of thermal performance of electronic package 220 which restricts the maximum power that can be used and dissipated by electronic package 220.

Therefore, an apparatus and method is needed for dispensing interface materials for electronic packages.

### SUMMARY

In some embodiment, an apparatus and a method for dispensing interface materials for electronic packages is described. According to some embodiment, a cooling radiator is attached to an electronic package using an adhesive interface material (e.g., on the perimeter, edges, distributed spots or the like). After the adhesive interface material is cured, a thermal interface material is dispensed thorough cavities (e.g., in the cooling radiator, adhesive interface material or the like). The thermal interface material is dispensed such that no gap is left between the adhesive interface material and the thermal interface material thus providing enhanced power dissipation for the electronic package. In another embodiment, a cooling radiator with one or more cavities (openings) is described. In some variation, one or more openings are used for dispensing thermal interface material. In some variation, one or more openings are used for air escape routes.

In some embodiments, the present application describes a method in connection with electronic packaging. The method includes dispensing a thermal interface material between an electronic package and a cooling radiator via at least one cavity. The method further includes attaching the cooling radiator to the electronic package with an adhesive interface material. In some variations, the adhesive interface material is applied on one or more edges of the electronic package. In some variations, the thermal interface material is dispensed between the edges of the electronic package. In some embodiments, the thermal interface material is applied after the adhesive interface material is cured. In some variations, the cavity is formed in the cooling radiator. In other variations, the cavity is formed in the adhesive interface material.

In some embodiment, the present application describes a circuit board assembly. In some variation, the circuit board assembly includes one or more electronic packages. In some variation, one or more the electronic packages include thermal interface material dispensed between the electronic packages and one or more cooling radiators via at least one cavity. In some variations, the cavities are created in the cooling radiator. In some embodiment, the cavities are created in adhesive interface material used to attach the cooling radiators to the electronic packages. In some embodiments, the adhesive interface material is applied on one or more edges of the electronic packages. In some variations, the thermal interface material is dispensed between the edges of the electronic package. In some variations, the thermal interface material is applied after the adhesive interface material is cured.

The foregoing is a summary and thus contains, by necessity, simplifications, generalizations and omissions of detail; consequently, those skilled in the art will appreciate that the summary is illustrative only and is not intended to be in any way limiting. Other aspects, inventive features, and advantages of the present invention, as defined solely by the claims, will become apparent in the non-limiting detailed description set forth below.

### BRIEF DESCRIPTION OF THE DRAWINGS

The present invention may be better understood, and its numerous objects, features, and advantages made apparent to those skilled in the art by referencing the accompanying drawings.

FIG. 1A illustrates an example of a typical use of interface material to attach a cooling radiator to an electronic package.

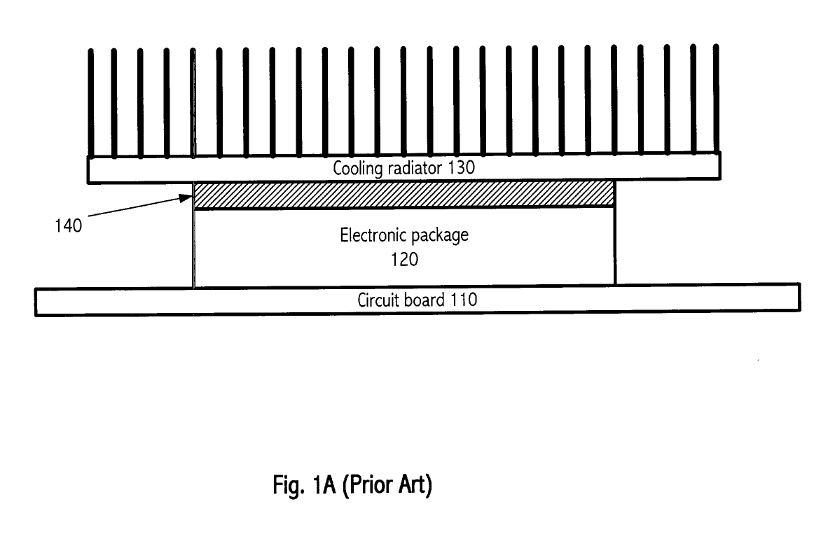

FIG. 1B is the top view of an electronic package with the cooling radiator removed, illustrating a typical use of interface material.

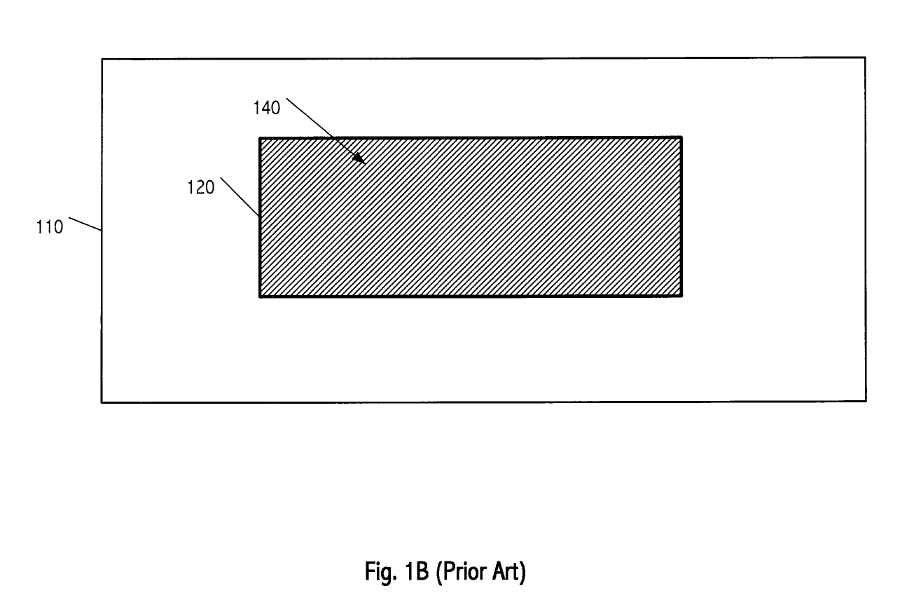

FIG. 2 is the top view of an electronic package without the cooling radiator illustrating a typical use of a combination of two interface materials for attaching the cooling radiator to the electronic package.

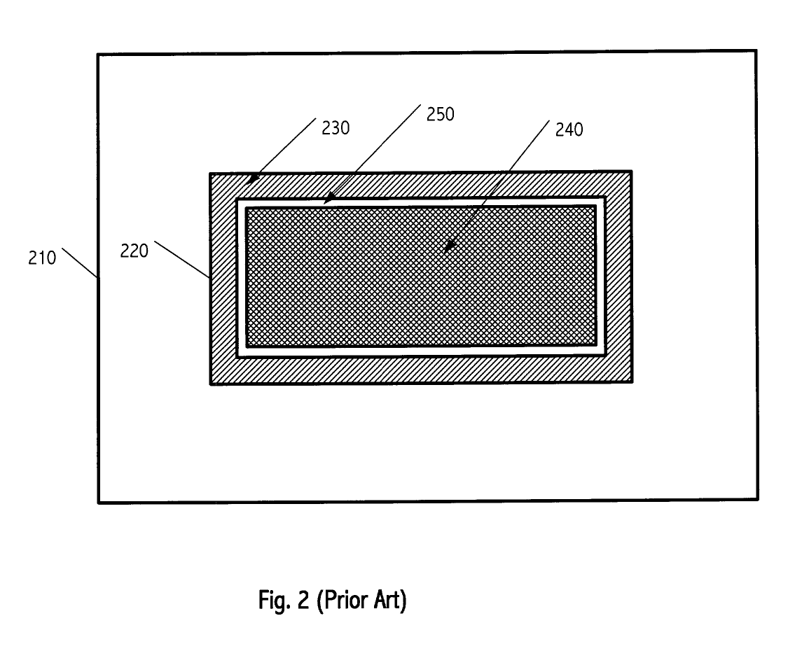

FIG. 3A illustrates an example a circuit board assembly 300 used for dispensing interface material for an electronic package according to an embodiment of the present invention.

FIG. 3B is top view of an electronic package without the cooling radiator illustrating the spread of a combination of interface materials according to one embodiment of the present invention.

FIG. 4 is a flow diagram illustrating an exemplary sequence of operations performed during a process of dispensing thermal interface material according to an embodiment of the present invention.

The use of the same reference symbols in different drawings indicates similar or identical items.

### DESCRIPTION OF THE PREFERRED EMBODIMENT(S)

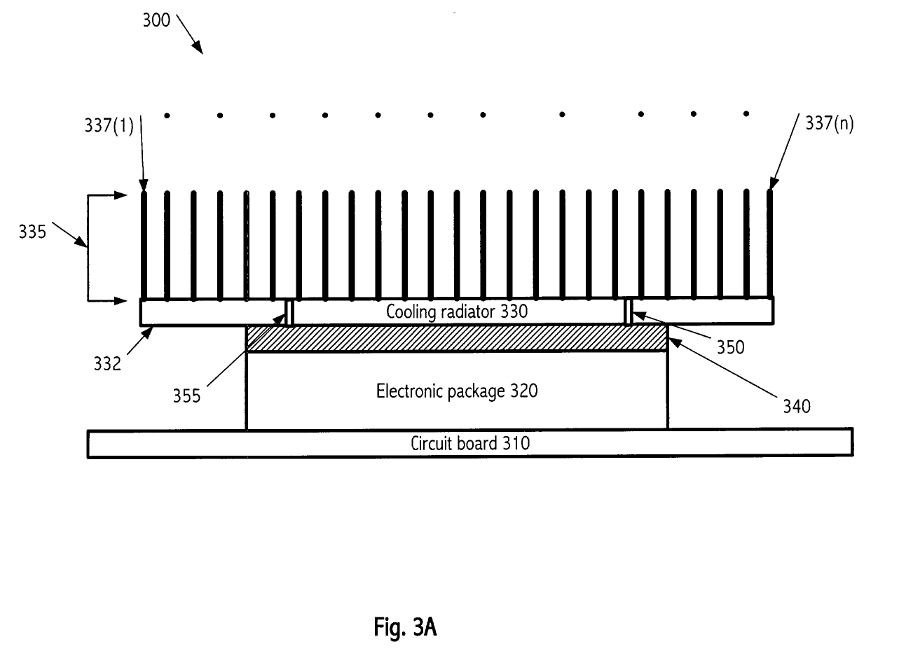

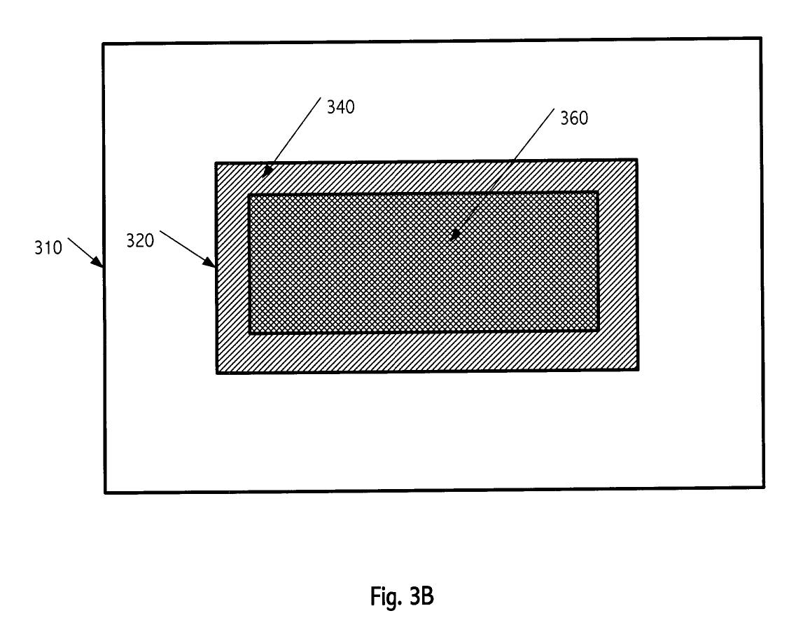

FIG. 3A illustrates an example a circuit board assembly 300 used for dispensing interface material for an electronic package according to an embodiment of the present invention. One skilled in the art will appreciate that the figure is not necessarily drawn to scale. Circuit board assembly 300 includes a circuit board 310. An electronic package 320 is attached to circuit board 310. For purposes of illustration, in the present example, a lidded electronic package is shown however, the electronic package can be a lidless bare die electronic package. Further, one electronic package is shown on circuit board 310 however one skilled in art will appreciate that generally, the circuit boards can include various electronic devices and components (e.g., integrated circuits, active and passive discrete components or the like). Electronic package 320 is attached to a cooling radiator 330. Cooling radiator 330 includes an attachment surface 332 and a heat dissipation portion 335. Heat dissipation portion 335 includes multiple heat dissipating elements 337(1)-(n). Heat dissipating elements 337(1)-(n) can be organized in any shape or form suitable for effective heat dissipation. While a row of heat dissipating elements 337(1)-(n) is shown, one skilled in art will appreciate that these elements can be organized in any form suitable for cooling radiator 330.

In the present example, attachment surface 332 is a substantially continuous surface area configured to provide a thermally conductive coupling with electronic package 320. Cooling radiator 330 is coupled to electronic package 320 via an adhesive interface material 340. Adhesive material 340 can be any material typically used to couple cooling radiators to electronic packages (e.g., Loctite 383™, 384™, 3873™ or the like). In the present example, heat dissipation portion 335 includes heat dissipating pins. While for illustration purpose, one row of pins is shown, one skilled in art will appreciate that heat dissipation portion 335 can include a matrix of heat dissipating elements (e.g., pins or the like) depending upon the size of the device. The characteristics of heat dissipation portion 335 (e.g., pin density, size, thickness or the like) can be configured according to the heat dissipation requirements of electronic package 320. Further, cooling radiator 330 can be configured for various types of electronic packages (e.g., through holes, surface mount, power modules or the like). Cooling radiator 330 can be of any form or shape configured to provide an appropriate thermally conductive interface for electronic packages (e.g., ‘U’ shape, ‘T’ shape or the like). While not shown, heat dissipating portion 335 can include one or more fans alone or in combination with heat dissipating elements to provide extra heat dissipation for electronic packages.

Adhesive material 340 is applied on electronic package 320 (e.g., on the edges, perimeters, selected spots or the like) leaving space for a thermal interface material. For purposes of illustrations, in the present example, adhesive material 340 is applied on the perimeter of electronic package 320 leaving the middle portions on the top of electronic package 320 empty. However, one skilled in art will appreciate that adhesive material 340 can be applied in various different ways to attach cooling radiator 330 to electronic package 320 depending on the physical characteristics (e.g., form, shape, strength, location on the circuit board or the like) of electronic package 320 and cooling radiator 330. Further, other attachment mechanism (e.g., clips, bolts or the like) can be used (alone or in combination thereof) to provide additional attachment support for cooling radiator 330.

For illustration purposes, in the present example, cooling radiator 330 includes two cavities, 350 and 355.After adhesive material 340 is cured, cavities 350 and 355 can be used to dispense a thermal interface material, not shown, (e.g., Thermoset MT-315™, Shin-Etsu G571™, Barqquist TIC7500™ or the like) to fill the empty space under cooling radiator 330 on the middle portion of electronic package 320. One of the cavities can be used to dispense thermal interface material and the other one can be used to allow the air or other gasses, trapped in the middle portion, to escape.

For purposes of illustration, in the present example, two cavities in cooling radiator 330 are described however, one skilled in art will appreciate that cooling radiator can include more (or less) cavities as required by the packaging process. For example, cooling radiator can include one cavity for dispensing the thermal interface material and the escape route for air can be created in the adhesive material (e.g., by leaving or creating space within the adhesive interface material or the like). While the cavities are described in the context of thermal interface material dispensing, one skilled in art will appreciate that the cavities can be used to dispense adhesive interface materials.

In some variation, when the adhesive material is not uniformly applied on the electronic packages then one cavity in cooling radiator can be used to dispense the thermal interface material. Similarly, multiple cavities in the cooling radiator can be created to improve the speed of thermal interface material dispensing. The location of the cavities in the cooling radiator can be chosen such to allow dispensing of thermal interface material on the electronic package. The embodiments described herein can be used in combination thereof. One skilled in art will appreciate that other means for creating cavities for thermal interface material dispensing are well within the scope of the embodiments described herein.

The cavities in the cooling radiators can be created using conventional tools or during the manufacturing of the cooling radiator. The location of cavities in the cooling radiator can be determined based on various design related factors (e.g., size, shape, strength, location on the circuit board of the electronic package and the cooling radiator, thermal interface material dispensing mechanisms or the like taken alone or in combination thereof). Similarly, the cavities in the adhesive interface material can be created using various adhesive interface material dispensing patterns for example, leaving space on the electronic packages without the interface material, adding air escape routes in the adhesive interface materials (e.g., adding tubes, removing sections of cured adhesive material or the like) or the like.

FIG. 3B is top view of electronic package 320 without cooling radiator 330 illustrating the spread of a combination of interface materials according to one embodiment of the present invention. In the present example, adhesive interface material 340 is applied on the perimeter of electronic package 320. When adhesive interface material 340 cures, thermal interface material 360 is dispensed at least through one of cavities 350 and 355 of cooling radiator 330. Because adhesive material 340 was cured before thermal interface material 360 is dispensed, a gap between the two interface materials is not needed. Thus, a better thermal interface can be formed between electronic package 320 and cooling radiator 330 allowing enhanced power dissipation capacity for electronic package 320.

According to some embodiments of the present inventions, one cavity can be used for non-continuous dispensing of thermal interface material thus allowing smooth dispensing of thermal material and allowing the air to escape through the same cavity. According to some other embodiment, other air escape routes can be configured to allow smooth dispensing of thermal interface material. For example, one or more cavities can be created in the adhesive material for air and other gases escape. According to some embodiment, the adhesive material can be dispensed in various forms and patterns, for example, the adhesive material can be dispensed sparingly on the electronic package thus creating various openings in the adhesive material allowing the dispensing of thermal interface material in between the adhesive material for example, for the use of cooling radiators that do not have cavities for dispensing thermal interface material. According to some embodiments, the cavity can be formed in the electronic package. One skilled in art will appreciate that the cavities can be formed in each individual element of the electronic package assembly or in a combination thereof. For example, one or more cavities can be formed in the cooling radiator and one or more cavities can be formed in the adhesive interface material or the electronic package or the like.

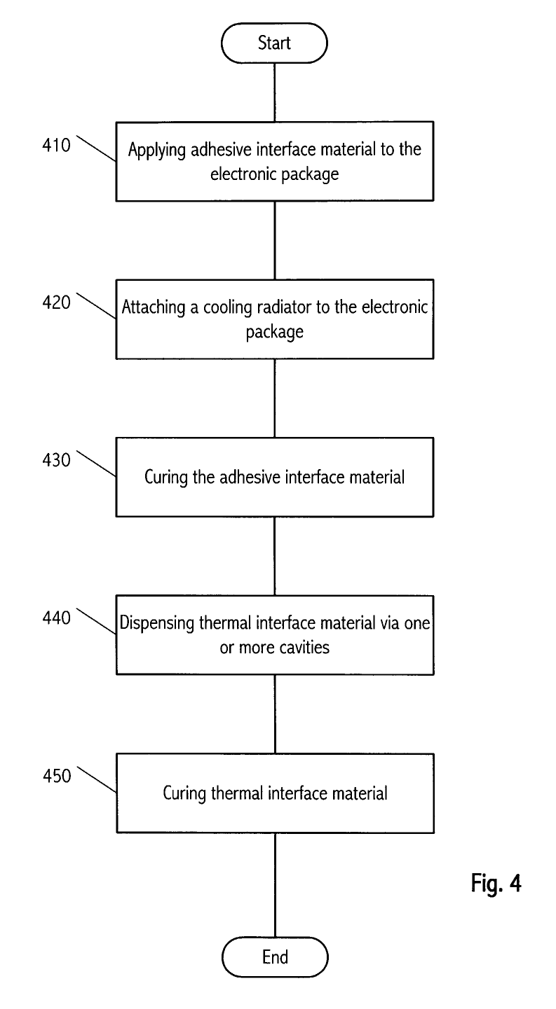

FIG. 4 is a flow diagram illustrating an exemplary sequence of operations performed during a process of dispensing thermal interface material according to an embodiment of the present invention. While the operations are described in a particular order, the operations described herein can be performed in other sequential orders (or in parallel) as long as dependencies between operations allow. In general, a particular sequence of operations is a matter of design choice and a variety of sequences can be appreciated by persons of skill in art based on the description herein.

Initially, the process applies adhesive interface material to an electronic package (410). As described herein, the adhesive material can be applied in various different forms (e.g., on the edges of the electronic package, on selected spots, dispensed sparingly or the like). The application of adhesive interface material can be adapted to the physical characteristics (e.g., form, shape, strength, location on a circuit board) of the electronic package and a cooling radiator to be attached to the electronic package. The process attaches the cooling radiator to the electronic package (420).

The process cures the adhesive interface material (430). The adhesive interface material is cured so that the thermal interface material can be dispensed without leaving a gap between the adhesive interface material and the thermal interface material. The process dispenses the thermal interface material via one or more cavities (440). The cavities can be defined in the cooling radiator, adhesive material or the like as described herein. The process cures the thermal interface material (450).

One skilled in art will appreciate that the concepts disclosed herein can be applied to various aspects of heat dissipation in electronic packaging. Similarly, the concepts disclosed herein can be adapted to any type of electronic packaging. Other variations, as will be appreciated by one skilled in art, are well within the scope of the present invention as defined by the claims herein. The above description is intended to describe at least one embodiment of the invention. The above description is not intended to define the scope of the invention. Rather, the scope of the invention is defined in the claims below. Thus, other embodiments of the invention include other variations, modifications, additions, and/or improvements to the above description.

While particular embodiments of the present invention have been shown and described, it will be obvious to those skilled in the art that, based upon the teachings herein, changes and modifications may be made without departing from this invention and its broader aspects and, therefore, the appended claims are to encompass within their scope all such changes and modifications as are within the true spirit and scope of this invention. Furthermore, it is to be understood that the invention is solely defined by the appended claims.

What is claimed is:

1. A method in connection with electronic packaging comprising:
dispensing a thermal interface material between an electronic package and a cooling radiator via at least one cavity.

2. The method of claim 1, wherein said cavity is formed in said cooling radiator.

3. The method of claim 1, wherein said cooling radiator is a heat sink.

4. The method of claim 1, wherein said electronic package is a bare die electronic package.

5. The method of claim 1, further comprising:
attaching said cooling radiator to said electronic package with an adhesive interface material.

6. The method of claim 5, wherein said thermal interface material is dispensed after said adhesive interface material is cured.

7. The method of claim 5, wherein said cavity is formed in said adhesive interface material.

8. The method of claim 5, wherein said adhesive interface material is applied on one or more edges of said electronic package.

9. The method of claim 8, wherein said thermal interface material is dispensed between said edges of said electronic package.

10. An apparatus, comprising:
an electronic package; and
a cooling radiator attached to said electronic package, wherein a thermal interface material is disposed between said electronic package and said cooling radiator via at least one cavity in said apparatus.

11. The apparatus of claim 10, wherein said cavity is formed in said cooling radiator.

12. The apparatus of claim 10, wherein said thermal interface material is disposed between said edges of said electronic package.

13. The apparatus of claim 10, wherein said cooling radiator is a heat sink.

14. The apparatus of claim 10, where in said electronic package is a bare die electronic package.

15. The apparatus of claim 10 wherein said cooling radiator is attached to said electronic package via an adhesive interface material.

16. The apparatus of claim 15, wherein said adhesive interface material is disposed proximate to one or more edges of said electronic package.

17. The apparatus of claim 15, wherein said thermal interface material is applied after said adhesive interface material is cured.

18. The apparatus of claim 15, wherein said cavity is formed in said adhesive interface material.

19. The apparatus of claim 10 further comprising:
a circuit board, wherein the electronic package is disposed proximate to said circuit board.

20. The apparatus of claim 19, wherein said electronic package is attached to said cooling radiator via an adhesive interface material.

21. The apparatus of claim 20, wherein said adhesive interface material is disposed proximate to one or more edges of said electronic package.

22. The apparatus of claim 19, wherein said thermal interface material is disposed between said edges of said electronic package.

23. The apparatus of claim 19, wherein said thermal interface material is applied after said adhesive interface material is cured.

24. The apparatus of claim 19, wherein said cavity is formed in said cooling radiator.

25. The apparatus of claim 19, wherein said cavity is formed in said adhesive interface material.

26. The apparatus of claim 19, wherein said electronic package is a bare die electronic package.

27. A cooling radiator comprising:
a first surface configured to dissipate heat, and
a second surface configured to be disposed proximate to an electronic package,
wherein said second surface includes at least one cavity configured for dispensing at least one interface material.

28. The cooling radiator of claim 27, wherein said second surface further comprises:
a second cavity configured to allow gas to escape.

29. The cooling radiator of claim 27, wherein said interface material is a thermal interface material.

30. The cooling radiator of claim 27, wherein said interface material is an adhesive interface material.

31. The cooling radiator of claim 27, wherein said second surface is further configured to dissipate heat.

32. The cooling radiator of claim 27, wherein said second surface is thermally coupled to said electronic package.

33. The cooling radiator of claim 27, wherein said first surface further comprises a plurality of heat dissipating elements.

34. The cooling radiator of claim 27, wherein said first surface further comprises at least one fan.

35. The cooling radiator of claim 27, wherein said electronic package is a bare die electronic package.

36. A method comprising:
dispensing a first viscous material to be in contact with first and second objects; and
applying a second viscous material to be in contact with the first and second objects wherein the dispensing of the second viscous material is done through at least one cavity in the second object.

37. The method of claim 36, wherein the second viscous material is applied after the first viscous material has cured.

38. The method of claim 36, further comprising:
providing the first and second viscous material such that the first viscous material as cured has an adhesive factor greater than the second viscous material.

39. The method of claim 36, further comprising:
selecting the first viscous material to have a greater thermal conductivity characteristics than a thermal conductive characteristic of the second viscous material.

40. The method of claim 36, wherein
the first object is an electronic package; and
the second object is a cooling radiator.

41. A method of providing an electronic package assembly, the electronic package assembly including an electronic package and a cooling radiator, the method comprising:
dispensing a thermal interface material between the electronic package and the cooling radiator via at least one cavity in the portion of the electronic package assembly.

42. The method of claim 41, wherein said cavity is formed in said cooling radiator.

43. The method of claim 41, wherein said cavity is formed in an adhesive material dispensed between said electronic package and said cooling radiator.

44. The method of claim 41, wherein said cavity is formed in said electronic package.

45. The method of claim 43, further comprising:
attaching said cooling radiator to said electronic package with said adhesive interface material.

46. The method of claim 43, wherein said thermal interface material is dispensed after said adhesive interface material is cured.
